(19) United States
(12) Patent Application Publication
(10) Pub. No.: US 2013/0119435 A1
(43) Pub. Date: May 16, 2013

(54) DIELECTRIC DUMMIFICATION FOR ENHANCED PLANARIZATION WITH SPIN-ON DIELECTRICS

(71) Applicant: Thomas Dungan, Fort Collins, CO (US)

(72) Inventor: Thomas Dungan, Fort Collins, CO (US)

(73) Assignee: Avago Technologies Wiresess IP (Singapore) Pte. Ltd., Singapore (SG)

(21) Appl. No.: 13/296,672

(22) Filed: Nov. 15, 2011

(51) Int. Cl. H01L 29/737; H01L 23/52; H01L 21/768

(52) U.S. Cl. 257/197; 438/637; 257/499; 257/E21.577; 257/E23.141; 257/E29.188

(57) ABSTRACT

An integrated device includes a lower layer pattern on a semiconductor substrate. The lower layer pattern includes a first region including first electrical devices and a second region including second electrical devices and electrically nonconductive dummy devices. A first device density of the first electrical devices in the first region is substantially greater than a second device density of the second electrical devices in the second region. A partially-planarizing dielectric layer is disposed on the lower layer pattern so as to cover the first electrical devices, the second electrical devices, and the electrically nonconductive dummy devices. The average height of the partially-planarizing dielectric layer in the first region is approximately the same as the average height in the second region. Through-holes are formed in the first region, and an electrically conductive material is disposed in the through-holes.

### BACKGROUND

Often, integrated circuits have different areas with significantly different device height profiles and/or significantly different device densities. However, when a partially-planarizing dielectric layer, such as benzocyclobutene, is applied to such an integrated circuit having different regions or areas with significantly different device densities, then the resultant dielectric layer can exhibit layout-dependent variations in thickness and global planarity between regions with greater device densities, and regions with lower device densities. In particular, the thickness and device coverage margin for the partially-planarizing dielectric layer in regions with higher device densities can be substantially greater than in regions with lower device densities. These layout-dependent thickness variations can have some undesirable consequences.

For example, topography-related photolithography complications can occur when fabricating upper layers or structures on top of the partially-planarizing dielectric layer when the height of the top surface of the partially-planarizing dielectric layer is substantially non-uniform.

Additionally, in some devices it is desired to provide through-holes which are used for providing an electrical connection between a terminal or structure (e.g., a conductive line) disposed in an upper layer above the partially-planarizing dielectric layer, and a terminal or device (e.g., a capacitor plate) disposed in a lower layer beneath the partially-planarizing dielectric layer. When the aspect ratio of such a through-hole typically becomes too great, then it becomes difficult or impossible to reliably fabricate the through-hole such that a good electrical (e.g., metal) connection is provided between the upper layer and the lower layer at the desired location, while avoiding undesired electrical shorts at other locations.

More specifically, when the designed width of a through-hole is reduced, it may be necessary to reduce the thickness of the partially-planarizing dielectric layer prior to etching the through-hole in order to maintain an acceptable aspect ratio, and/or to etch the partially-planarizing dielectric layer for a longer time to make the through-hole with a higher aspect ratio. However, when the partially-planarizing dielectric layer has a greater thickness and device coverage margin in a first region where the through-hole is to be produced than in a second region where the device density is substantially less, then if the thickness of the partially-planarizing dielectric layer is globally reduced to facilitate production of a through-hole in the first (“higher density”) region with a reduced width or diameter, the coverage margin may become insufficient in the second (“lower density”) region such that the partially-planarizing dielectric layer may be etched through in the second region when the through-hole is fabricated, thereby exposing, damaging, or causing an electrical short circuit to a device in the second region from a conductive layer or upper layer structure. In addition to the imperative to prevent such an electrical short between an upper layer device and a lower layer device, it is often also important that a parasitic capacitance coupling density between an upper layer structure and a lower layer structure due to the partially-planarizing dielectric material is about the same in first region as in second region

What is needed, therefore, is a method of enhancing the global planarization of an integrated circuit which employs a partially-planarizing dielectric, particularly in the case where the integrated circuit has two or more regions with substantially different device densities than each other. What is also needed is an integrated circuit with a partially-planarizing dielectric layer that can exhibit an enhanced global planarization.

### SUMMARY

In one aspect of the inventive concept, a method comprises: fabricating a lower layer pattern on a semiconductor substrate. The lower layer pattern includes a first region including first electrical devices and a second region including second electrical devices and one or more electrically nonconductive dummy devices. The first device density of the first electrical devices in the first region is substantially greater than the second device density of the second electrical devices in the second region. An average height above the substrate of the lower layer pattern in the second region, is substantially greater than a value obtained by calculating an average height above the substrate of the lower layer pattern in the second region when the one or more electrically nonconductive dummy devices are assigned a height above the substrate equal to zero. The method also includes providing a partially-planarizing dielectric layer on the lower layer pattern so as to cover the first electrical devices, the second electrical devices, and the electrically nonconductive dummy devices, wherein the average height above the substrate of a top surface of the partially-planarizing dielectric layer in the first region is approximately the same as the average height above the substrate of the top surface of the partially-planarizing dielectric layer in the second region. The method further includes etching the partially-planarizing dielectric layer in the first region and in the second region so as to form a plurality of through-holes in the first region while leaving a portion of the planarizing dielectric layer covering top surfaces of the second electrical devices in the second region; and providing an electrically conductive material in the through-holes.

In one or more embodiments, the average height above the substrate of the one or more electrically nonconductive dummy devices is approximately the same as the average height above the substrate of the second electrical devices.

In one or more embodiments, fabricating the lower layer pattern includes: providing a dummy dielectric material onto the substrate; masking and patterning the dummy dielectric material to remove a first portion of the dummy dielectric material and to leave a remaining portion of the dummy dielectric material; and hardening the remaining portion of the dummy dielectric material to produce the one or more electrically nonconductive dummy devices.

In one or more embodiments, the dummy dielectric material comprises polyimide.

In one or more embodiments, the partially-planarizing dielectric layer comprises benzocyclobutene (BCB).

In one or more embodiments, the one or more electrically nonconductive dummy devices comprise a plurality of dielectric structures that are separated and spaced apart from the second electrical devices.

In one or more embodiments, the average height above the substrate of top surfaces of the lower layer pattern in the second region is approximately the same as the average height above the substrate of top surfaces of the lower layer pattern in the first region.

In one or more embodiments, the first electrical devices comprise heterojunction bipolar transistors (HBTs).

In another aspect of the inventive concept, an integrated circuit comprises: a lower layer pattern disposed on a semiconductor die, wherein the lower layer pattern includes a first region including first electrical devices and a second region including second electrical devices and one or more electrically nonconductive dummy devices, wherein a first density of the first electrical devices in the first region is substantially greater than a second device density of the second electrical devices in the second region, and wherein an average height above the substrate of the one or more electrically nonconductive dummy devices is substantially the same as an average height above the substrate of the second electrical devices; a partially-planarizing dielectric layer on the lower layer pattern, wherein the partially-planarizing dielectric layer covers the second electrical devices and the electrically nonconductive dummy devices, wherein a plurality of through-holes are provided in the partially-planarizing dielectric layer in the first region, wherein at least one of the through-holes is disposed above one of the first electrical devices, and wherein an average height above the substrate of a top surface of the partially-planarizing dielectric layer in the first region is approximately the same as the average height above the substrate of the top surface of the partially-planarizing dielectric layer in the second region; and an electrically conductive material disposed in the at least one through-hole disposed above the at least one first electrical device so as to provide an electrical contact to the at least one first electrical device.

In one or more embodiments, the average height above the substrate of top surfaces of the one or more electrically nonconductive dummy devices is approximately the same as the average height above the substrate of top surfaces of the second electrical devices.

In one or more embodiments, the one or more electrically nonconductive dummy devices comprise polyimide.

In one or more embodiments, the partially-planarizing dielectric layer comprises benzocyclobutene (BCB).

In one or more embodiments, the one or more electrically nonconductive dummy devices comprise a plurality of isolated dielectric structures.

In one or more embodiments, the average height above the substrate of the lower layer pattern in the second region is approximately the same as the average height above the substrate of the lower layer pattern in the first region.

In one or more embodiments, the first electrical devices comprise heterojunction bipolar transistors (HBTs).

In yet another aspect of the inventive concept, a method comprises: fabricating a lower layer pattern on a semiconductor substrate, wherein the lower layer pattern includes a first region including first electrical devices and a second region including second electrical devices and one or more electrically nonconductive dummy devices, wherein a first density of the first electrical devices in the first region is substantially greater than a second device density of the second electrical devices in the second region; providing a partially-planarizing dielectric layer on the lower layer pattern so as to cover the first electrical devices, the second electrical devices, and the electrically nonconductive dummy devices, wherein an average height above the substrate of a top surface of the partially-planarizing dielectric layer in the first region is approximately the same as the average height above the substrate of the top surface of the partially-planarizing dielectric layer in the second region; etching the partially-planarizing dielectric layer in the first region and in the second region so as to form a plurality of through-holes in the first region while leaving a portion of the planarizing dielectric layer covering top surfaces of the second electrical devices in the second region; and providing an electrically conductive material in the through-holes.

In one or more embodiments, the average height above the substrate of top surfaces of the one or more electrically nonconductive dummy devices is substantially the same as the average height above the substrate of top surfaces of the second electrical devices.

In one or more embodiments, the average height above the substrate of a top surface of the lower layer pattern in the second region is approximately the same as the average height above the substrate of the top surface of the lower layer pattern in the first region.

In one or more embodiments, fabricating the lower layer pattern includes: providing a dummy dielectric material onto the substrate; masking and patterning the dummy dielectric material to remove a first portion of the dummy dielectric material and to leave a remaining portion of the dummy dielectric material; and hardening the remaining portion of the dummy dielectric material to produce the one or more electrically nonconductive dummy devices.

In one or more embodiments, the dummy dielectric material comprises polyimide, and wherein the partially-planarizing dielectric layer comprises benzocyclobutene (BCB).

In still another aspect of the inventive concept, an integrated device includes a lower layer pattern on a semiconductor substrate. The lower layer pattern includes a first region including first electrical devices and a second region including second electrical devices and electrically nonconductive dummy devices. A first density of the first electrical devices in the first region is substantially greater than a second device density of the second electrical devices in the second region. A partially-planarizing dielectric layer is disposed on the lower layer pattern so as to cover the first electrical devices, the second electrical devices, and the electrically nonconductive dummy devices. The average height the partially-planarizing dielectric layer in the first region is approximately the same as the average height in the second region. Through-holes are formed in the first region, and an electrically conductive material is disposed in the through-holes.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A-C illustrate a portion of a fabrication process of making an integrated circuit.

FIGS. 2A-C illustrate a first example of a portion of a fabrication process of making an integrated circuit in a case where the device density in a region of the integrated circuit is increased.

FIGS. 3A-C illustrate a second example of a portion of a fabrication process of making an integrated circuit in a case where the device density in a region of the integrated circuit is increased.

FIGS. 4A-C illustrate a third example of a portion of a fabrication process of making an integrated circuit in a case where the device density in a region of the integrated circuit is increased.

FIGS. 5A-E illustrate a fourth example of a portion of a fabrication process of making an integrated circuit in a case where the device density in a region of the integrated circuit is increased.

FIGS. 6A-C illustrate an example embodiment of a portion of a fabrication process of making an integrated circuit with dummy dielectric structures for improving the planarization of a dielectric layer.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

Unless otherwise noted, when a first device is said to be connected to a second device, this encompasses cases where one or more intermediate devices may be employed to connect the two devices to each other. However, when a first device is said to be directly connected to a second device, this encompasses only cases where the two devices are connected to each other without any intermediate or intervening devices. Similarly, when a signal is said to be coupled to a device, this encompasses cases where one or more intermediate devices may be employed to couple the signal to the device. However, when a signal is said to be directly coupled to a device, this encompasses only cases where the signal is directly coupled to the device without any intermediate or intervening devices.

As used herein, when two values are said to be “approximately the same” it means that they are within 10% of each other. By contrast, when a first thickness, height, density, value, etc. is said to “significantly greater” that a second thickness, height, density, value, etc., it means that the first thickness, height, density, value, etc. is at least 10% greater than the second thickness, height, density, value, etc. When two values are said to be “substantially the same” it means that they are within 25% of each other. By contrast, when a first thickness, height, density, value, etc. is said to “substantially greater” that a second thickness, height, density, value, etc., it means that the first thickness, height, density, value, etc. is at least 25% greater than the second thickness, height, density, value, etc.

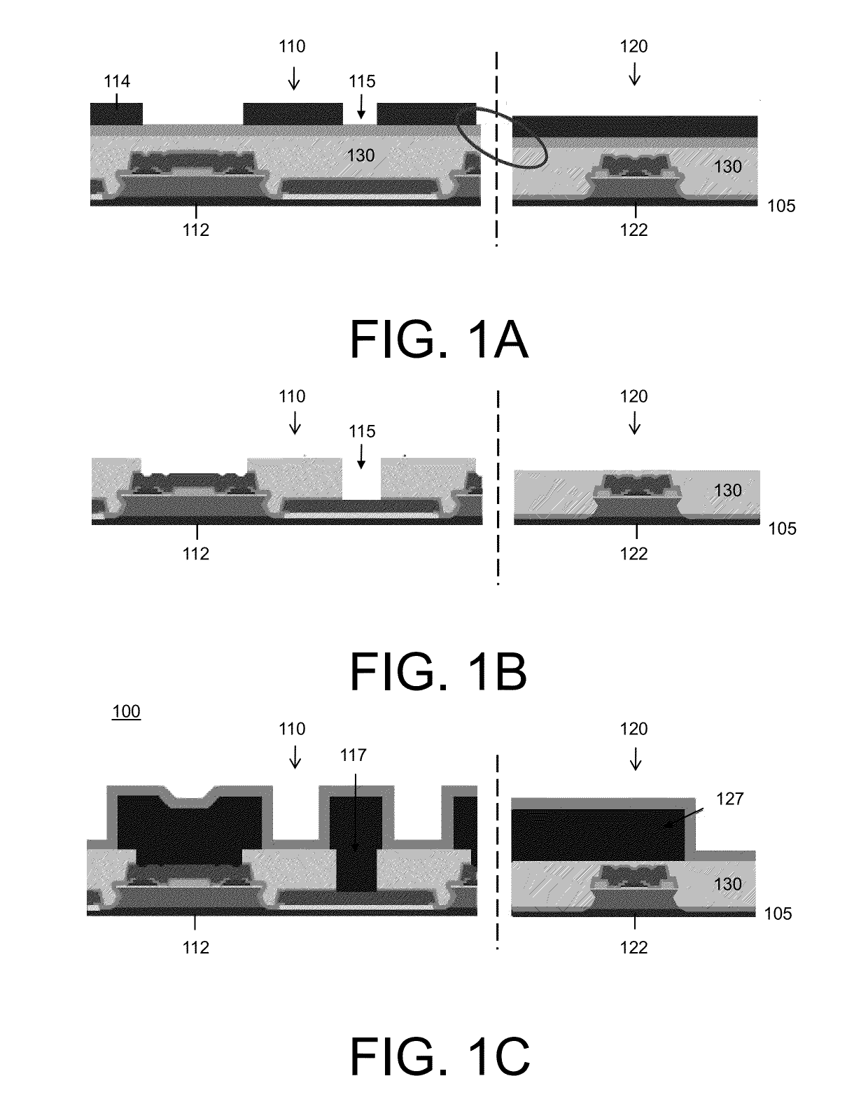

FIGS. 1A-C illustrate a portion of a fabrication process of making an integrated circuit 100. Integrated circuit 100 includes a lower layer pattern formed on a substrate 105. Here, the lower layer pattern means all of the devices, structure, layers, and materials that remain on substrate 105 when partially-planarizing dielectric material 130 is applied to substrate 105. The lower layer pattern has a first region 110 and a second region 120. In some embodiments, the complete fabrication process for integrated circuit 100 may include providing one or more additional dielectric layers and/or metal layers, not specifically illustrated in FIGS. 1A-C, for one or more upper layers on top of partially-planarizing dielectric material 130

The first region 110 includes a plurality of first electrical devices 112, and optionally one or more first passive electrical devices. In some embodiments, first electrical devices 112 comprise transistors, and the one or more first passive electrical devices include a capacitor. In some embodiments, first electrical devices 112 comprise heterojunction bipolar transistors (HBTs).

Second region 120 includes a plurality of second electrical devices 122, and optionally one or more second passive electrical devices. In some embodiments, second electrical devices 122 comprise transistors, and the one or more second passive electrical devices include a capacitor. In some embodiments, first electrical devices 122 comprise heterojunction bipolar transistors (HBTs).

Of significance, the device density of first electrical devices 112 in first region 110 is substantially greater than the device density of second electrical devices 122 in second region 120. In some embodiments, the device density of first electrical devices 112 in first region 110 is much greater than the device density of second electrical devices 122 in second region 120—for example 50% greater, or twice as great, or more. As a result, the average height above substrate 105 of the lower layer pattern in first region 110 is substantially greater than the average height above substrate 105 of the lower layer pattern in second region 120.

As shown in FIG. 1A, a partially-planarizing dielectric material 130 is provided on the lower layer pattern in both first region 110 and second region 120. The partially-planarizing dielectric material 130 is a material that can provide “local planarization” over a localized area, but which does not provide global planarization over a larger area where there are significant differences over the larger area in the average local height profiles of devices or structures which are covered by the material 130. One example of a partially-planarizing dielectric material 130 is benzocyclobutene (BCB).

Of significance, because the device density in first region 110 is substantially greater than the device density in second region 120, then the height above substrate 105 of partially-planarizing dielectric material 130 in first region 110 is substantially greater than the height above substrate 105 of partially-planarizing dielectric material 130 in second region 120. That is, while a height of partially-planarizing dielectric material may be substantially uniform in first region 110, and may also be substantially uniform in second region 120, the average height in first region 110 may be substantially greater than in second region 120.

As also shown in FIG. 1A, a hardmask (not labeled) and a resist mask pattern 114 are provided on partially-planarizing dielectric material 130 to define areas where partially-planarizing dielectric material 130 is to be etched.

As shown in FIG. 1B, partially-planarizing dielectric material 130 is etched to define through-holes 115 therethrough. Although the drawings illustrate a through-hole 115 provided in first region 110, in some embodiments one or more through-holes 115 may be provided in second region 120. One or more of through-holes 115 may be provided above one or more first electrical devices 112. During this etching process, it is possible that a hard mask (not labeled) and other portions of partially-planarizing dielectric material 130 outside of the areas for through-holes 115 will also be etched. Accordingly, as shown in FIG. 1B, after the etching of through-holes 115 is completed, then the height above substrate 105 of partially-planarizing dielectric material 130 in both first region 110 and second region 120 is reduced. As shown in FIG. 1B, because the height above substrate 105 of partially-planarizing dielectric material 130 is substantially less in second region 120 than in first region 110, there is a reduced coverage margin of partially-planarizing dielectric material 130 above second electrical devices 122.

As shown in FIG. 1C, a first electrically conductive material 117 (e.g., a metal) is provided (e.g., deposited) in through-holes 115 and may contact first electrical devices 112. Also, a second electrically conductive material 127 (e.g., a metal) is provided on partially-planarizing dielectric material 130 in second region 120. Partially-planarizing dielectric material 130 prevents second electrically conductive material 127 from contacting or electrically shorting to second electrical devices 122—that is, it electrically isolates second electrically conductive material 127 from second electrical devices 122.

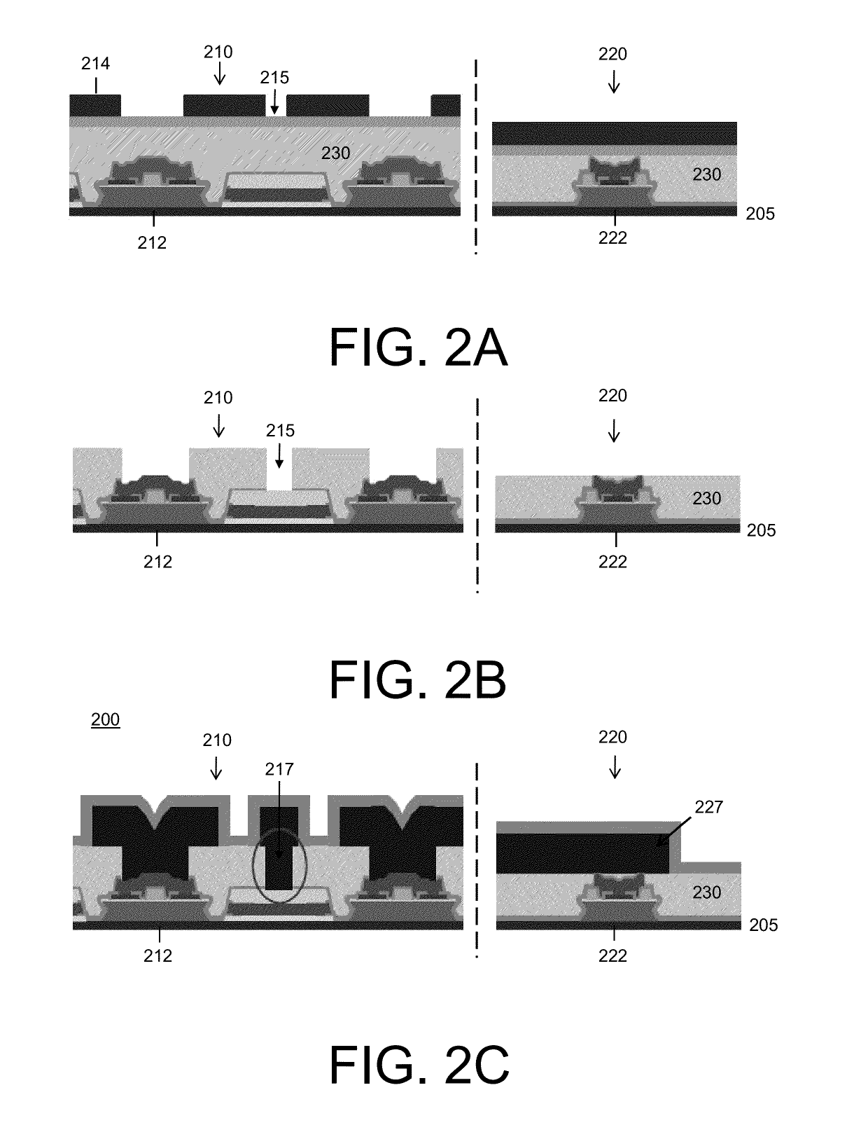

FIGS. 2A-C illustrate a first example of a portion of a fabrication process of making an integrated circuit 200. Integrated circuit 200 includes a lower layer pattern formed on a substrate 205. Here, the lower layer pattern refers to all of the devices, structure, layers, and materials that remain on substrate 205 when a partially-planarizing dielectric material 230 is applied to substrate 205. The lower layer pattern has a first region 210 and a second region 220. In some embodiments, the complete fabrication process for integrated circuit 200 may include providing one or more additional dielectric layers and/or metal layers, not specifically illustrated in FIGS. 2A-C, for one or more upper layers on top of partially-planarizing dielectric material 230.

In particular, the width(s) or diameter(s) of one of more through-holes to be fabricated for integrated circuit 200 are reduced in comparison to integrated circuit 100 of FIGS. 1A-C.

The first region 210 includes a plurality of first electrical devices 212, and optionally one or more first passive electrical devices. In some embodiments, first electrical devices 212 comprise transistors, and the one or more first passive electrical devices may include a capacitor and/or a thin-film resistor, etc. In some embodiments, first electrical devices 212 comprise heterojunction bipolar transistors (HBTs).

Second region 220 includes a plurality of second electrical devices 222, and optionally one or more second passive electrical devices. In some embodiments, second electrical devices 222 comprise transistors, and the one or more second passive electrical devices include a capacitor. In some embodiments, first electrical devices 222 comprise heterojunction bipolar transistors (HBTs).

Of significance, the device density of first electrical devices 212 in first region 210 is substantially greater than the device density of second electrical devices 222 in second region 220. In some embodiments, the device density of first electrical devices 212 in first region 210 is much greater than the device density of second electrical devices 222 in second region 220—for example 50% greater, or twice as great, or more. As a result, the average height above substrate 205 of the lower layer pattern in first region 210 is substantially greater than the average height above substrate 105 of the lower layer pattern in second region 220.

As shown in FIG. 2A, a partially-planarizing dielectric material 230 is provided on the lower layer pattern in both first region 210 and second region 220. The partially-planarizing dielectric material 230 is a material that can provide “local planarization” over a localized area, but which does not provide global planarization over a larger area where there are significant differences over the larger area in the average local height profiles of devices or structures which are covered by the material 230. One example of a partially-planarizing dielectric material 230 is benzocyclobutene (BCB).

Of significance, because the device density in first region 210 is substantially greater than the device density in second region 220, then the height above substrate 205 of partially-planarizing dielectric material 230 in first region 210 is substantially greater than the height above substrate 205 of partially-planarizing dielectric material 230 in second region 220. That is, while a height of partially-planarizing dielectric material may be substantially uniform in first region 210, and may also be substantially uniform in second region 220, the average height in first region 210 may be substantially greater than in second region 220.

As also shown in FIG. 2A, a hardmask (not labeled) and a resist mask pattern 214 are provided on partially-planarizing dielectric material 230 to define areas where partially-planarizing dielectric material 230 is to be etched.

As shown in FIG. 2B, partially-planarizing dielectric material 230 is etched to define through-holes 215 therethrough. Although the drawings illustrate a through-hole 215 provided in first region 210, in some embodiments one or more through-holes 215 may be provided in second region 220. One or more of through-holes 215 may be provided above one or more first electrical devices 212. During this etching process, it is possible that a hard mask (not labeled) and other portions of partially-planarizing dielectric material 230 outside of the areas for through-holes 215 will also be etched. Accordingly, as shown in FIG. 2B, after the etching of through-holes 215 is completed, then the height above substrate 205 of partially-planarizing dielectric material 230 in both first region 210 and second region 220 is reduced.

As noted above, the width of through-holes 215 in integrated circuit 200 is less than the width of through-holes 115 in integrated circuit 100. As explained above, to reliably make the through-holes 215 with the reduced width, it becomes necessary to: (1) reduce employ a partially-planarizing dielectric layer 230 having a reduced thickness prior to etching through-holes 215 so as to reduce the aspect ratio of through-holes 215; and/or (2) etch partially-planarizing dielectric layer 230 for a longer time to make through-holes 215 with the higher aspect ratio.

In the example illustrated in FIGS. 2A-C, the thickness of partially-planarizing dielectric layer 230 prior to etching the through-hole has been maintained, and the partially-planarizing dielectric layer 230 it etched for a longer time to make the through-hole with the higher aspect ratio.

As shown in FIG. 2B, because the height above substrate 205 of partially-planarizing dielectric material 230 is substantially less in second region 220 than in first region 210, there is a reduced coverage margin of partially-planarizing dielectric material 230 above second electrical devices 222. In particular, in the example illustrated in FIGS. 2A-C, because of the need to etch partially-planarizing dielectric layer 230 for a longer time to make the through-hole with the higher aspect ratio, the coverage margin for partially-planarizing dielectric layer 230 in region 220 is eliminated and the top surface of second electrical device 222 is exposed by the etching process.

As shown in FIG. 2C, a first electrically conductive material 217 (e.g., a metal) is provided (e.g., deposited) in through-holes 215 and may contact first electrical devices 212. Also, a second electrically conductive material 227 (e.g., a metal) is provided on partially-planarizing dielectric material 230 in second region 220.

However, because the coverage margin of partially-planarizing dielectric material 230 in second region 220 has been eliminated, second electrical devices 222 may be damaged in the etching process and/or second electrically conductive material 227 may contact or electrically short to the top surface of second electrical devices 222.

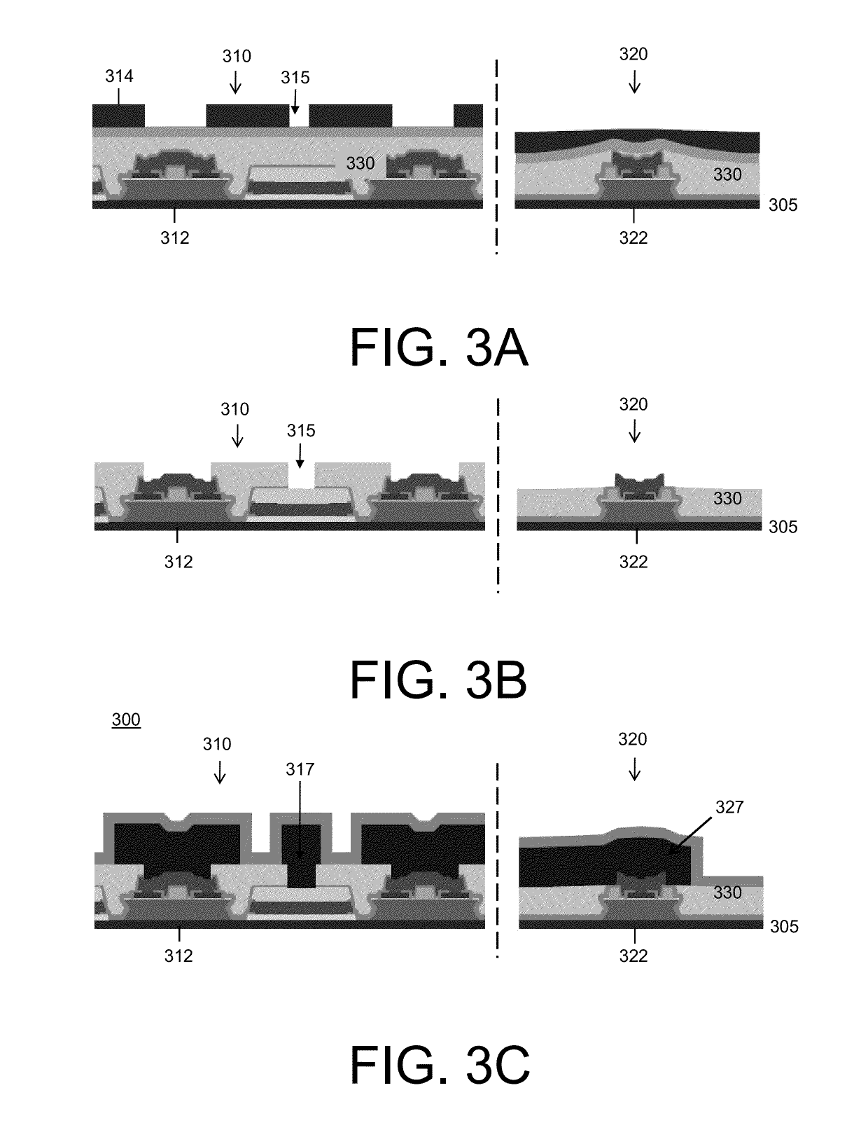

FIGS. 3A-C illustrate a second example of a portion of a fabrication process of making an integrated circuit 300 in a case where the device density in a region of the integrated circuit is increased. Integrated circuit 300 includes a lower layer pattern formed on a substrate 305. Here, the lower layer pattern means all of the devices, structure, layers, and materials that remain on substrate 305 when a partially-planarizing dielectric material 330 is applied to substrate 305. The lower layer pattern has a first region 310 and a second region 320. In some embodiments, the complete fabrication process for integrated circuit 300 may include providing one or more additional dielectric layers and/or metal layers, not specifically illustrated in FIGS. 3A-C, for one or more upper layers on top of partially-planarizing dielectric material 330.

In particular, the width(s) or diameter(s) of one of more through-holes to be fabricated for integrated circuit 300 are reduced in comparison to integrated circuit 100 of FIGS. 1A-C.

The first region 310 includes a plurality of first electrical devices 312, and optionally one or more first passive electrical devices. In some embodiments, first electrical devices 312 comprise transistors, and the one or more first passive electrical devices include a capacitor. In some embodiments, first electrical devices 312 comprise heterojunction bipolar transistors (HBTs).

Second region 320 includes a plurality of second electrical devices 322, and optionally one or more second passive electrical devices. In some embodiments, second electrical devices 322 comprise transistors, and the one or more second passive electrical devices include a capacitor. In some embodiments, first electrical devices 322 comprise heterojunction bipolar transistors (HBTs).

Of significance, the device density of first electrical devices 312 in first region 310 is substantially greater than the device density of second electrical devices 322 in second region 320. In some embodiments, the device density of first electrical devices 312 in first region 310 is much greater than the device density of second electrical devices 322 in second region 320—for example 50% greater, or twice as great, or more. As a result, the average height above substrate 305 of the lower layer pattern in first region 310 is substantially greater than the average height above substrate 305 of the lower layer pattern in second region 320.

As shown in FIG. 3A, a partially-planarizing dielectric material 330 is provided on the lower layer pattern in both first region 310 and second region 320. The partially-planarizing dielectric material 330 is a material that can provide “local planarization” over a localized area, but which does not provide global planarization over a larger area where there are significant differences over the larger area in the average local height profiles of devices or structures which are covered by the material 330. One example of a partially-planarizing dielectric material 330 is benzocyclobutene (BCB).

Of significance, because the device density in first region 310 is substantially greater than the device density in second region 320, then the height above substrate 305 of partially-planarizing dielectric material 330 in first region 310 is substantially greater than the height above substrate 305 of partially-planarizing dielectric material 330 in second region 320. That is, while a height of partially-planarizing dielectric material may be substantially uniform in first region 310, and may also be substantially uniform in second region 320, the average height in first region 310 may be substantially greater than in second region 320.

As also shown in FIG. 3A, a hardmask (not labeled) and a resist mask pattern 314 are provided on partially-planarizing dielectric material 330 to define areas where partially-planarizing dielectric material 330 is to be etched. As shown in FIG. 3B, partially-planarizing dielectric material 330 is etched to define through-holes 315 therethrough. Although the drawings illustrate a through-hole 315 provided in first region 310, in some embodiments one or more through-holes 315 may be provided in second region 320. One or more of through-holes 315 may be provided above one or more first electrical devices 312. During this etching process, it is possible that a hard mask (not labeled) and other portions of partially-planarizing dielectric material 330 outside of the areas for through-holes 315 will also be etched. Accordingly, as shown in FIG. 3B, after the etching of through-holes 315 is completed, then the height above substrate 305 of partially-planarizing dielectric material 330 in both first region 310 and second region 320 is reduced.

As noted above, the device density in region 310 in integrated circuit 300 is increased with respect to the device density in region 110 for integrated circuit 100. Accordingly, the width of through-holes 315 in integrated circuit 300 is less than the width of through-holes 115 in integrated circuit 100.

Therefore, in the illustrated example, to reliably make the through-holes 315, the thickness or height of partially-planarizing dielectric layer 330 prior to etching through-holes 315 is reduced in comparison to the thickness or height of partially-planarizing dielectric layer 130 of FIGS. 1A-C, so as to reduce the aspect ratio of through-holes 315.

As shown in FIG. 3B, because the height above substrate 305 of partially-planarizing dielectric material 330 is substantially less in second region 320 than in first region 310, there is a reduced coverage margin of partially-planarizing dielectric material 330 above second electrical devices 322. In particular, in the example illustrated in FIGS. 3A-C, because of the reduced thickness of partially-planarizing dielectric layer 330 so as to reduce the aspect ratio of through-holes 315, the coverage margin for partially-planarizing dielectric layer 330 in region 320 is eliminated and the top surface of second electrical device 322 is exposed by the etching process.

As shown in FIG. 3C, a first electrically conductive material 317 (e.g., a metal) is provided (e.g., deposited) in through-holes 315 and may contact first electrical devices 312. Also, a second electrically conductive material 327 (e.g., a metal) is provided on partially-planarizing dielectric material 330 in second region 320.

However, because the coverage margin of partially-planarizing dielectric material 330 in second region 320 has been eliminated, second electrical devices 322 may be damaged in the etching process and/or second electrically conductive material 327 may contact or electrically short to the top surface of second electrical devices 322.

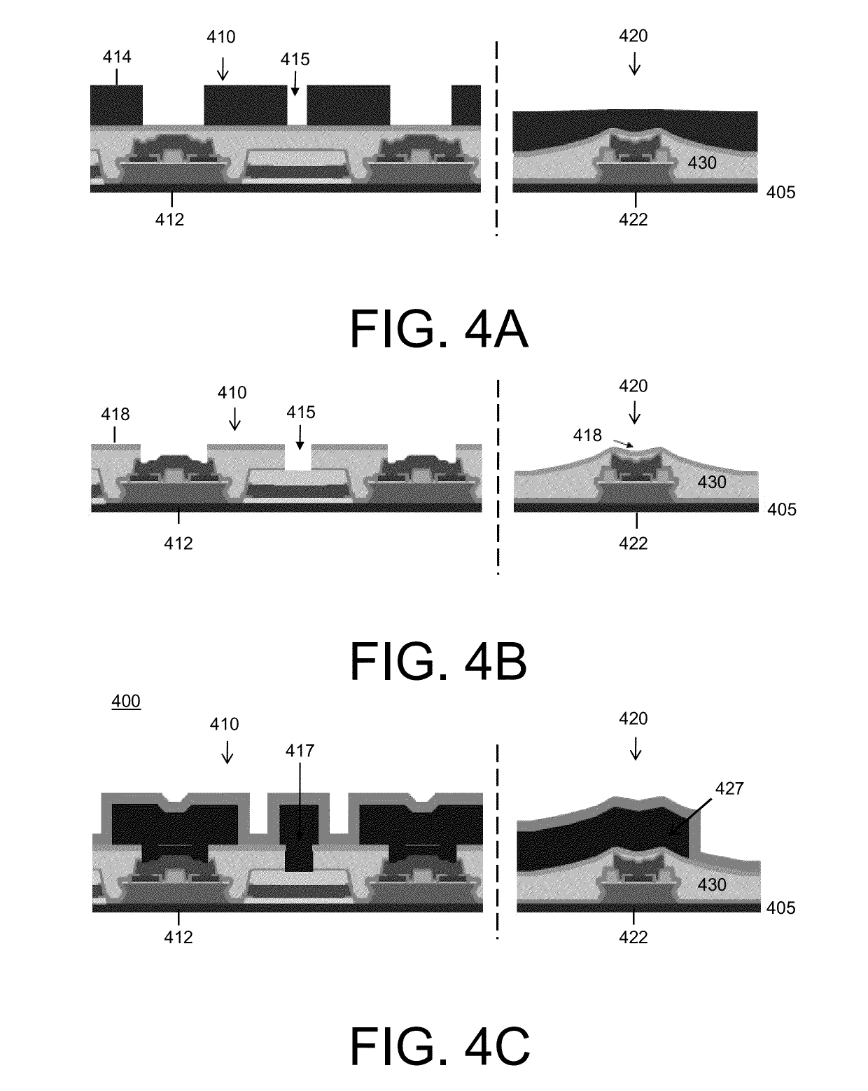

FIGS. 4A-C illustrate a third example of a portion of a fabrication process of making an integrated circuit in a case where the device density in a region of the integrated circuit is increased. Integrated circuit 400 includes a lower layer pattern formed on a substrate 405. Here, the lower layer pattern means all of the devices, structure, layers, and materials that remain on substrate 405 when partially-planarizing dielectric material 430 is applied to substrate 405. The lower layer pattern has a first region 410 and a second region 420. In some embodiments, the complete fabrication process for integrated circuit 400 may include providing one or more additional dielectric layers and/or metal layers, not specifically illustrated in FIGS. 4A-C, for one or more upper layers on top of partially-planarizing dielectric material 430.

In particular, the width(s) or diameter(s) of one of more through-holes to be fabricated for integrated circuit 400 are reduced in comparison to integrated circuit 100 of FIGS. 1A-C.

The first region 410 includes a plurality of first electrical devices 412, and optionally one or more first passive electrical devices. In some embodiments, first electrical devices 412 comprise transistors, and the one or more first passive electrical devices include a capacitor. In some embodiments, first electrical devices 412 comprise heterojunction bipolar transistors (HBTs).

Second region 420 includes a plurality of second electrical devices 422, and optionally one or more second passive electrical devices. In some embodiments, second electrical devices 422 comprise transistors, and the one or more second passive electrical devices include a capacitor. In some embodiments, first electrical devices 422 comprise heterojunction bipolar transistors (HBTs).

Of significance, the device density of first electrical devices 412 in first region 410 is substantially greater than the device density of second electrical devices 422 in second region 420. In some embodiments, the device density of first electrical devices 412 in first region 410 is much greater than the device density of second electrical devices 422 in second region 420—for example 50% greater, or twice as great, or more. As a result, the average height above substrate 405 of the lower layer pattern in first region 410 is substantially greater than the average height above substrate 405 of the lower layer pattern in second region 420.

As shown in FIG. 4A, a partially-planarizing dielectric material 430 is provided on the lower layer pattern in both first region 410 and second region 420. The partially-planarizing dielectric material 430 is a material that can provide “local planarization” over a localized area, but which does not provide global planarization over a larger area in a case where there are significant differences over the larger area in the average local height profiles of devices or structures which are covered by the material 430. One example of a partially-planarizing dielectric material 430 is benzocyclobutene (BCB).

Of significance, because the device density in first region 410 is substantially greater than the device density in second region 420, then the height above substrate 405 of partially-planarizing dielectric material 430 in first region 410 is substantially greater than the height above substrate 405 of partially-planarizing dielectric material 430 in second region 420. That is, while a height of partially-planarizing dielectric material may be substantially uniform in first region 410, and may also be substantially uniform in second region 420, the average height in first region 410 may be substantially greater than in second region 420.

As also shown in FIG. 4A, a hardmask 418 and a resist mask pattern 414 are provided on partially-planarizing dielectric material 430 to define areas where partially-planarizing dielectric material 430 is to be etched. Here, mask pattern 414 is thicker than mask patterns 114, 214, and 314 of FIGS. 1A-C, 2A-C, and 3A-C, respectively. Also, the thickness of hardmask 418 may be less than the thickness of the hard mask (not labeled) in FIGS. 1A-C, 2A-C, and 3A-C.

As shown in FIG. 4B, partially-planarizing dielectric material 430 is etched to define through-holes 415 therethrough. Although the drawings illustrate a through-hole 415 provided in first region 410, in some embodiments one or more through-holes 415 may be provided in second region 420. One or more of through-holes 415 may be provided above one or more first electrical devices 412. Here, the thickness or height of partially-planarizing dielectric layer 430 prior to etching through-holes 415 is reduced in comparison to the thickness or height of partially-planarizing dielectric layer 130 of FIGS. 1A-C, so as to reduce the aspect ratio of through-holes 415.

In the example of FIGS. 4A-C, hard mask 418 is preserved in the etching process, particularly in the area above second electrical devices 422. Accordingly, during this etching process, a coverage margin of partially-planarizing dielectric material 430 above second electrical devices 422 may be maintained.

As shown in FIG. 4C, a first electrically conductive material 417 (e.g., a metal) is provided (e.g., deposited) in through-holes 415 and may contact first electrical devices 412. Also, a second electrically conductive material 427 (e.g., a metal) is provided on partially-planarizing dielectric material 430 and hard mask 418 in second region 420. Because the coverage margin of partially-planarizing dielectric material 430 and hard mask 418 above second electrical devices 422 may be maintained, damage to second electrical devices 422 and an electrical short between second electrically conductive material 427 and the top surface of second electrical devices 422 may be avoided.

Although in some cases of increased device densities in region 410, the coverage margin of partially-planarizing dielectric material 430 in second region 420 may be maintained by the process illustrated in FIGS. 4A-C, there is limit to how small the width or diameter of through-holes 415 may be made before the coverage margin of partially-planarizing dielectric material 430 and hard mask 418 above second electrical devices 422 is eliminated.

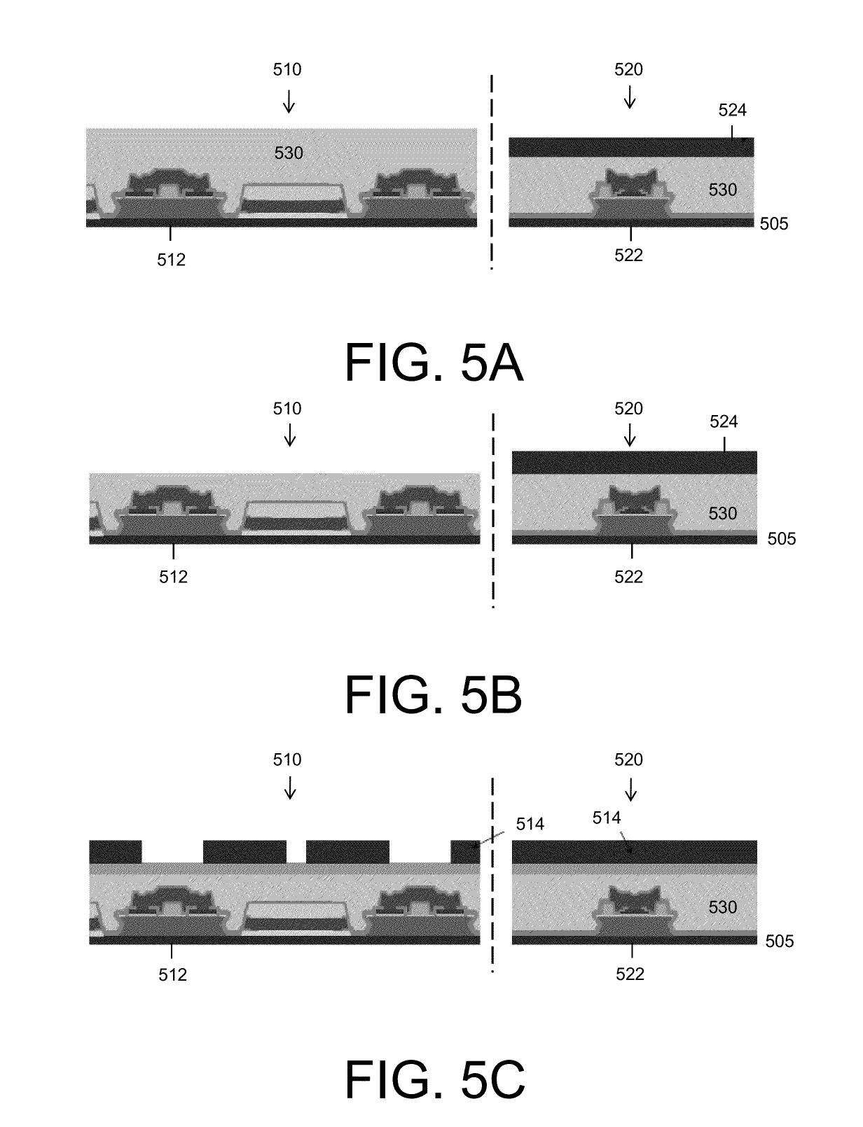

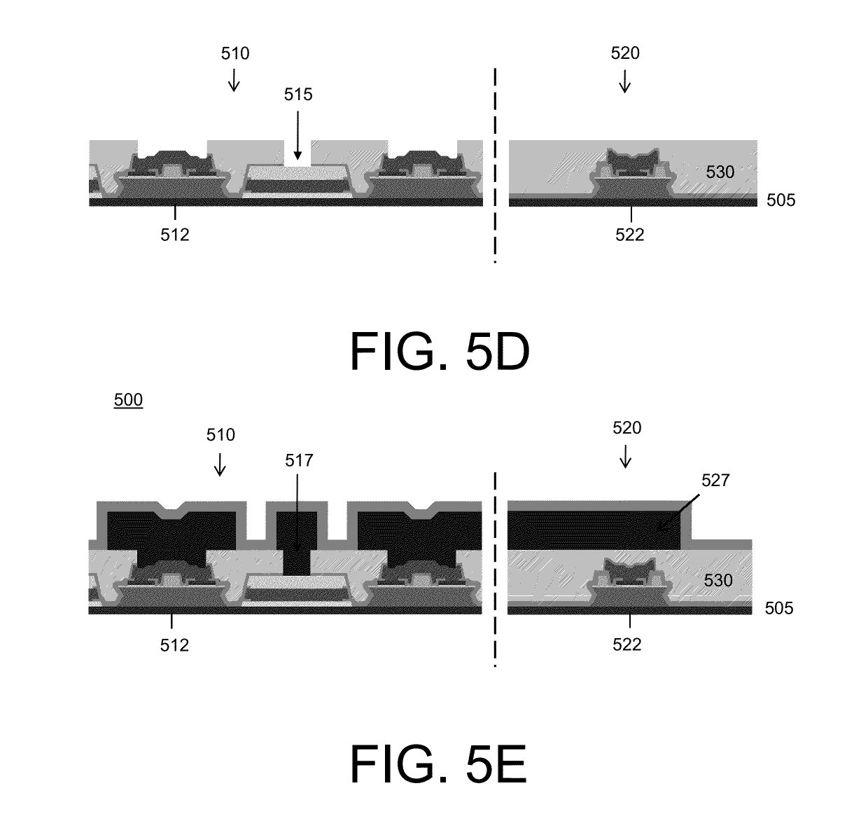

FIGS. 5A-E illustrate a fourth example of a portion of a fabrication process of making an integrated circuit in a case where the device density in a region of the integrated circuit is increased. Integrated circuit 500 includes a lower layer pattern formed on a substrate 505. Here, the lower layer pattern means all of the devices, structure, layers, and materials that remain on substrate 505 when partially-planarizing dielectric material 530 is applied to substrate 505. The lower layer pattern has a first region 510 and a second region 520. In some embodiments, the complete fabrication process for integrated circuit 500 may include providing one or more additional dielectric layers and/or metal layers, not specifically illustrated in FIGS. 5A-E, for one or more upper layers on top of partially-planarizing dielectric material 530.

In particular, the width(s) or diameter(s) of one of more through-holes to be fabricated for integrated circuit 500 are reduced in comparison to integrated circuit 100 of FIGS. 1A-C.

The first region 510 includes a plurality of first electrical devices 512, and optionally one or more first passive electrical devices. In some embodiments, first electrical devices 512 comprise transistors, and the one or more first passive electrical devices include a capacitor. In some embodiments, first electrical devices 512 comprise heterojunction bipolar transistors (HBTs).

Second region 520 includes a plurality of second electrical devices 522, and optionally one or more second passive electrical devices. In some embodiments, second electrical devices 522 comprise transistors, and the one or more second passive electrical devices include a capacitor. In some embodiments, first electrical devices 522 comprise heterojunction bipolar transistors (HBTs).

Of significance, the device density of first electrical devices 512 in first region 510 is substantially greater than the device density of second electrical devices 522 in second region 520. In some embodiments, the device density of first electrical devices 512 in first region 510 is much greater than the device density of second electrical devices 522 in second region 520—for example 50% greater, or twice as great, or more. As a result, the average height above substrate 505 of the lower layer pattern in first region 510 is substantially greater than the average height above substrate 505 of the lower layer pattern in second region 520.

As shown in FIG. 5A, a partially-planarizing dielectric material 530 is provided on the lower layer pattern in both first region 510 and second region 520. The partially-planarizing dielectric material 530 is a material that can provide “local planarization” over a localized area, but which does not provide global planarization over a larger area where there are significant differences over the larger area in the average local height profiles of devices or structures which are covered by the material 530. One example of a partially-planarizing dielectric material 530 is benzocyclobutene (BCB).

Of significance, because the device density in first region 510 is substantially greater than the device density in second region 520, then the height above substrate 505 of partially-planarizing dielectric material 530 in first region 510 is substantially greater than the height above substrate 505 of partially-planarizing dielectric material 530 in second region 520. That is, while a height of partially-planarizing dielectric material may be substantially uniform in first region 510, and may also be substantially uniform in second region 520, the average height in first region 510 may be substantially greater than in second region 520.

As noted above, the device density in region 510 in integrated circuit 500 is increased with respect to the device density in region 110 for integrated circuit 100. Accordingly, the width of through-holes 515 in integrated circuit 500 is less than the width of through-holes 115 in integrated circuit 100.

Therefore, in the illustrated example, to reliably make the through-holes 515, the thickness of partially-planarizing dielectric layer 530 in first region 510 is reduced prior to etching through-holes 515 so as to reduce the aspect ratio of through-holes 515.

Toward this end, as shown in FIG. 5A an etch-back mask 524 is applied to partially-planarizing dielectric material 530 in second region 520.

As shown in FIG. 5B, partially-planarizing dielectric material 530 is etched back in a timed etch back process to reduce the thickness or the height above substrate 505 of partially-planarizing dielectric material 530 in first region 510. The etch back must be timed so as to reduce the thickness or the height above substrate 505 of partially-planarizing dielectric material 530 in first region 510 by a desired amount, while still maintaining an adequate coverage for first electrical devices 512. During this etch-back process, etch-back mask 524 prevents etching of partially-planarizing dielectric material 530 in second region 520. As a result of the etch-back process, the thickness or height above substrate 505 of partially-planarizing dielectric material 530 in first region 510 becomes substantially the same, or approximately the same, as the thickness or height above substrate 505 of partially-planarizing dielectric material 530 in second region 520.

Then, as shown in FIG. 5C, partially-planarizing dielectric material 530 is etched to define through-holes 515 therethrough. Although the drawings illustrate a through-hole 515 provided in first region 510, in some embodiments one or more through-holes 515 may be provided in second region 520. One or more of through-holes 515 may be provided above one or more first electrical devices 512. The rest of the process proceeds in similarity to the process illustrated in FIGS. 3A-C above. In particular, as shown in FIG. 5D partially-planarizing dielectric material 530 is etched to define through-holes 515 therethrough. One or more of through-holes 515 may be provided above one or more first electrical devices 512. Then, as illustrated in FIG. 5E, a first electrically conductive material 517 (e.g., a metal) is provided (e.g., deposited) in through-holes 515 and may contact first electrical devices 512. Also, a second electrically conductive material 527 (e.g., a metal) is provided on partially-planarizing dielectric material 530 in second region 520.

Because the coverage margin of partially-planarizing dielectric material 530 in second region 520 may be maintained, damage to second electrical devices 522 and an electrical short between second electrically conductive material 527 and the top surface of second electrical devices 522 may be avoided.

However, only a single timed etch back target is possible for a range of effective device densities. So a margin must be allowed for this and for variation in the timed etch. Therefore, there is limit to how small the width of through-holes 515 may be before the coverage margin of partially-planarizing dielectric material 530 above second electrical devices 522 is eliminated.

So it is seen that there are certain shortcomings involved in each of the processes illustrated in FIGS. 1A-C through FIGS. 5A-E described above.

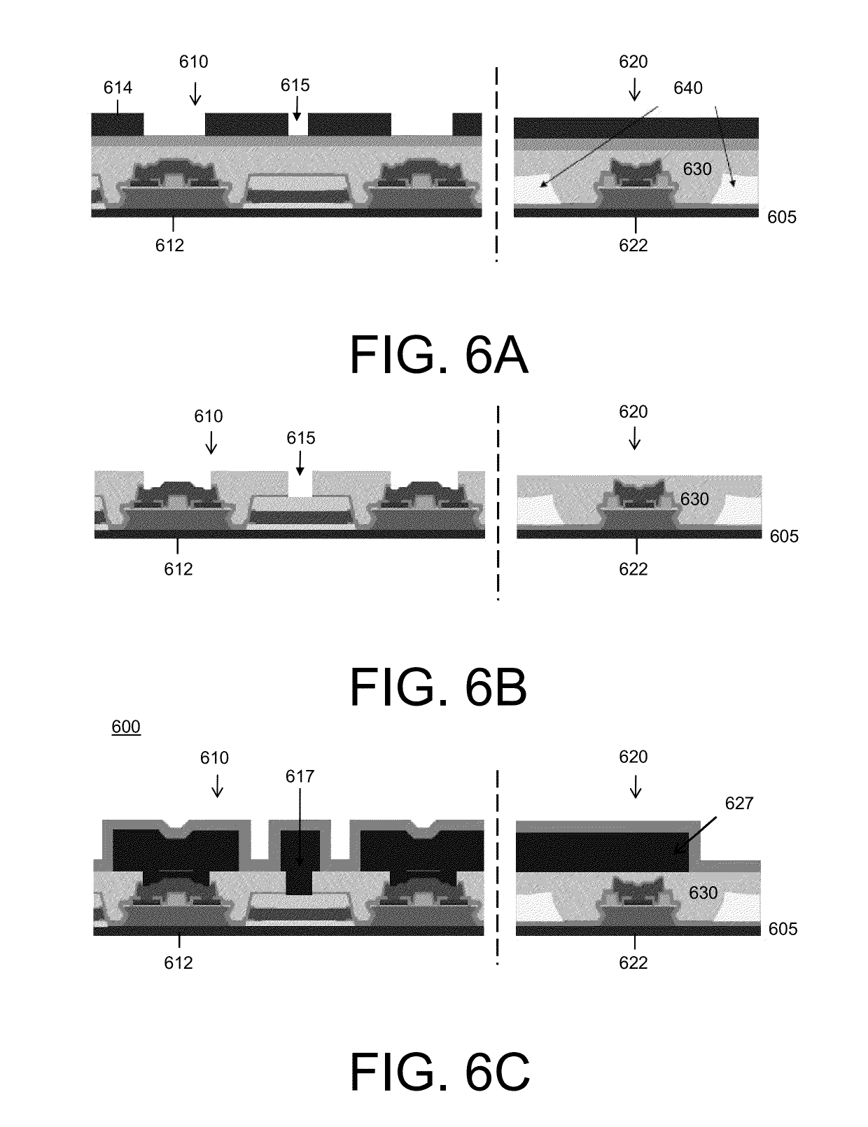

Accordingly, FIGS. 6A-C illustrate an example embodiment of a portion of a fabrication process of making an integrated circuit 600 with dummy dielectric structures for improving the planarization of a dielectric layer. Integrated circuit 600 includes a lower layer pattern formed on a substrate 605. Here, the lower layer pattern refers to all of the devices, structure, layers, and materials that remain on substrate 605 when partially-planarizing dielectric material 630 is applied to substrate 605. The lower layer pattern has a first region 610 and a second region 620. In some embodiments, the complete fabrication process for integrated circuit 600 may include providing one or more additional dielectric layers and/or metal layers, not specifically illustrated in FIGS. 6A-C, for one or more upper layers on top of partially-planarizing dielectric material 630.

In particular, the width(s) or diameter(s) of one of more through-holes to be fabricated for integrated circuit 600 are reduced in comparison to integrated circuit 100 of FIGS. 1A-C.

The first region 610 includes a plurality of first electrical devices 612, and optionally one or more first passive electrical devices. In some embodiments, first electrical devices 612 comprise transistors, and the one or more first passive electrical devices include a capacitor. In some embodiments, first electrical devices 612 comprise heterojunction bipolar transistors (HBTs).

Second region 620 includes a plurality of second electrical devices 622, and optionally one or more second passive electrical devices. In some embodiments, second electrical devices 622 comprise transistors, and the one or more second passive electrical devices include a capacitor. In some embodiments, first electrical devices 622 comprise heterojunction bipolar transistors (HBTs).

Of significance, the device density of first electrical devices 612 in first region 610 is substantially greater than the device density of second electrical devices 622 in second region 620. In some embodiments, the device density of first electrical devices 612 in first region 610 is much greater than the device density of second electrical devices 622 in second region 620—for example 50% greater, or twice as great, or more.

As shown in FIG. 6A, a partially-planarizing dielectric material 630 is provided on the lower layer pattern in both first region 610 and second region 620. The partially-planarizing dielectric material 630 is a material that can provide “local planarization” over a localized area, but which does not provide global planarization over a larger area in a case where there are significant differences over the larger area in the average local height profiles of devices or structures which are covered by the material 630. One example of a partially-planarizing dielectric material 630 is benzocyclobutene (BCB).

Of significance, because the device density in first region 610 is substantially greater than the device density in second region 620, then if no other measures were taken, the height above substrate 605 of partially-planarizing dielectric material 630 in first region 610 would be substantially greater than the height above substrate 605 of partially-planarizing dielectric material 630 in second region 620. That is, while the height of partially-planarizing dielectric material may be substantially uniform in first region 610, and may also be substantially uniform in second region 620, then if no other measures were taken, the average height in first region 610 would be substantially greater than in second region 620.

Accordingly, to address this problem, as shown in FIG. 6A integrated circuit 600 includes one or more dummy devices or structures 640 in second region 620 between second electrical devices 622 prior to the provision of partially-planarizing dielectric material 630 so as to increase the average height above substrate 605 of the lower layer pattern in the second region 620.

Here, dummy devices or structures 640 are devices or structures which do not participate in the electrical operation of integrated circuit 600, but instead are provided to increase the average height profile in second region 620 to facilitate manufacturing of integrated circuit 600. Beneficially, dummy devices 640 are electrically nonconductive dummy devices. Beneficially, electrically nonconductive dummy devices 640 are physically separated and spaced apart from second devices 622. Beneficially, electrically nonconductive dummy devices 640 are electrically isolated from second devices 622. In some embodiments, the average height above the substrate of top surfaces of electrically nonconductive dummy devices 640 may be approximately the same as an average height above the substrate of top surfaces of the second electrical devices 622. Beneficially, electrically nonconductive dummy devices 640 are not sacrificial structures that are removed in subsequent processing steps, but instead remain present in the final integrated circuit 600 after fabrication. Also beneficially, electrically nonconductive dummy devices 640 are not themselves etch stop or barrier layers that prevent etch-though, but instead these are devices which increase the average height or profile of the lower payer pattern in second region 620 to more closely match the average height or profile of the lower payer pattern in first region 610.

As noted above, electrically nonconductive dummy devices 640 are provided in second region 620 prior to application of partially-planarizing dielectric material 630 to increase the average height above substrate 605 of the lower layer pattern in first region 620. In particular, in some embodiments the average height above substrate 605 of the lower layer pattern in second region 620 including electrically nonconductive dummy devices 640, is substantially greater than a value obtained by calculating the average height above substrate 605 of the lower layer pattern in second region 620 if the one or more electrically nonconductive dummy devices are assigned a height above substrate 605 of zero. As a result of the addition of electrically nonconductive dummy devices 640, in some embodiments the average height above substrate 605 of the lower layer pattern in first region 610 may be substantially the same as the average height above substrate 605 of the lower layer pattern in second region 620.

In some embodiments, electrically nonconductive dummy devices 640 may be fabricated by providing a dummy dielectric material onto the substrate; masking and patterning the dummy dielectric material to remove a first portion of the dummy dielectric material and to leave a remaining portion of the dummy dielectric material; and curing or hardening the remaining portion of the dummy dielectric material to produce the one or more electrically nonconductive dummy devices 640. In some embodiments, the dummy dielectric material comprises polyimide (and therefore the electrically nonconductive dummy devices 640 comprise polyimide).

At some point after the electrically nonconductive dummy devices 640 are fabricated in second region 620, partially-planarizing dielectric material 630 is provided on substrate 605 in both first region 610 and second region 620 to cover the lower layer pattern in first region 610 and the lower layer pattern in second region 620. Due to the presence of nonconductive dummy devices 640 in second region 620, partially-planarizing dielectric material 630 may achieve a greater degree of global planarization. Beneficially, the average height above substrate 605 of a top surface of partially-planarizing dielectric layer 630 in first region 610 is approximately the same as the average height above substrate 605 of the top surface of partially-planarizing dielectric layer 630 in second region 620.

At some point after partially planarizing dielectric material 630 is provided on substrate 605, then as shown in FIG. 6A a mask pattern 614 is applied to the partially-planarizing dielectric material 630 to define areas where partially-planarizing dielectric material 630 is to be etched.

As shown in FIG. 6B, partially-planarizing dielectric material 630 is etched to define through-holes 615 therethrough. Although the drawings illustrate a through-hole 615 provided in first region 610, in some embodiments one or more through-holes 615 may be provided in second region 620. One or more of through-holes 615 may be provided above one or more first electrical devices 612. During this etching process, it is possible that other portions of partially-planarizing dielectric material 630 will be etched outside of the areas for through-holes 615. Accordingly, as shown in FIG. 6B, after the etching of through-holes 615 is completed, then the height above substrate 605 of partially-planarizing dielectric material 630 in both first region 610 and second region 620 is reduced.

As noted above, the device density in region 610 in integrated circuit 600 is increased with respect to the device density in region 110 for integrated circuit 100. Accordingly, the width of through-holes 615 in integrated circuit 600 is less than the width of through-holes 115 in integrated circuit 100.

As shown in FIG. 6B, because the height above substrate 605 of partially-planarizing dielectric material 630 is substantially the same in second region 620 as in first region 610, a coverage margin of partially-planarizing dielectric material 630 above second electrical devices 622 is maintained.

As shown in FIG. 6C, a first electrically conductive material 617 (e.g., a metal) is provided (e.g., deposited) in through-holes 615 and may contact first electrical devices 612. Also, a second electrically conductive material 627 (e.g., a metal) is provided on partially-planarizing dielectric material 630 in second region 620.

Because the coverage margin of partially-planarizing dielectric material 630 in second region 620 has been maintained by the provision of electrically nonconductive dummy devices 640 in second region 620, damage to second electrical devices 622 and an electrical short between second electrically conductive material 627 and the top surface of second electrical devices 622 may be avoided. Additionally, because of the approximately uniform global height of partially-planarizing dielectric material 630 in first region 610 and second region 620, a capacitance between an upper layer to be formed on partially-planarizing dielectric material 630 and the lower layer structure is about the same in first region 610 as in second region 620.

While example embodiments are disclosed herein, one of ordinary skill in the art appreciates that many variations that are in accordance with the present teachings are possible and remain within the scope of the appended claims. For example, although the descriptions and figures above illustrate an exemplary case where a matching network multiplexes signals to and from an antenna and a plurality of filters, the matching network is not limited to use with an antenna. In general, any appropriate device, such as a broadband amplifier or filter, can be passively multiplexed with the plurality of filters using the matching network as described above. The embodiments therefore are not to be restricted except within the scope of the appended claims.

1. A method, comprising:
fabricating a lower layer pattern on a semiconductor substrate, wherein the lower layer pattern includes a first region including first electrical devices and a second region including second electrical devices and one or more electrically nonconductive dummy devices, wherein a first device density of the first electrical devices in the first region is substantially greater than a second device density of the second electrical devices in the second region, and wherein (1) an average height above the substrate of the lower layer pattern in the second region, is substantially greater than (2) a value obtained by calculating an average height above the substrate of the lower layer pattern in the second region when the one or more electrically nonconductive dummy devices are assigned a height above the substrate equal to zero;
providing a partially-planarizing dielectric layer on the lower layer pattern so as to cover the first electrical devices, the second electrical devices, and the electrically nonconductive dummy devices, wherein an average height above the substrate of a top surface of the partially-planarizing dielectric layer in the first region is approximately the same as the average height above the substrate of the top surface of the partially-planarizing dielectric layer in the second region;
etching the partially-planarizing dielectric layer in the first region and in the second region so as to form a plurality of through-holes in the first region while leaving a portion of the planarizing dielectric layer covering top surfaces of the second electrical devices in the second region; and
providing an electrically conductive material in the through-holes.

2. The method of claim 1, wherein an average height above the substrate of top surfaces of the one or more electrically nonconductive dummy devices is approximately the same as an average height above the substrate of top surfaces of the second electrical devices.

3. The method of claim 1, wherein fabricating the lower layer pattern includes:
providing a dummy dielectric material onto the substrate;
masking and patterning the dummy dielectric material to remove a first portion of the dummy dielectric material and to leave a remaining portion of the dummy dielectric material; and
hardening the remaining portion of the dummy dielectric material to produce the one or more electrically nonconductive dummy devices.

4. The method of claim 3, wherein the dummy dielectric material comprises polyimide.

5. The method of claim 4, wherein the partially-planarizing dielectric layer comprises benzocyclobutene (BCB).

6. The method of claim 1, wherein the one or more electrically nonconductive dummy devices comprise a plurality of dielectric structures that are separated and spaced apart from the second electrical devices.

7. The method of claim 1, wherein the average height above the substrate of a top surface of the lower layer pattern in the second region is approximately the same as the average height above the substrate of the top surface of the lower layer pattern in the first region.

8. The method of claim 1, wherein the first electrical devices comprise heterojunction bipolar transistors (HBTs).

9. An integrated circuit, comprising:
a lower layer pattern disposed on a semiconductor die, wherein the lower layer pattern includes a first region including first electrical devices and a second region including second electrical devices and one or more electrically nonconductive dummy devices, wherein a first device density of the first electrical devices in the first region is substantially greater than a second device density of the second electrical devices in the second region, and wherein an average height above the substrate of the one or more electrically nonconductive dummy devices is substantially the same as an average height above the substrate of the second electrical devices;
a partially-planarizing dielectric layer on the lower layer pattern, wherein the partially-planarizing dielectric layer covers the second electrical devices and the electrically nonconductive dummy devices, wherein a plurality of through-holes are provided in the partially-planarizing dielectric layer in the first region, wherein at least one of the through-holes is disposed above one of the first electrical devices, and wherein an average height above the substrate of a top surface of the partially-planarizing dielectric layer in the first region is approximately the same as the average height above the substrate of the top surface of the partially-planarizing dielectric layer in the second region; and
an electrically conductive material disposed in the at least one through-hole disposed above the at least one first electrical device so as to provide an electrical contact to the at least one first electrical device.

10. The integrated circuit of claim 9, wherein an average height above the substrate of the one or more electrically nonconductive dummy devices is approximately the same as an average height above the substrate of the second electrical devices.

11. The integrated circuit of claim 9, wherein the one or more electrically nonconductive dummy devices comprise polyimide.

12. The integrated circuit of claim 9, wherein the partially-planarizing dielectric layer comprises benzocyclobutene (BCB).

13. The integrated circuit of claim 9, wherein the one or more electrically nonconductive dummy devices comprise a plurality of isolated dielectric structures.

14. The integrated circuit of claim 9, wherein the average height above the substrate of the top surface of the lower layer pattern in the second region is approximately the same as the average height above the substrate of the top surface of the lower layer pattern in the first region

15. The integrated circuit of claim 9, wherein the first electrical devices comprises heterojunction bipolar transistors (HBTs).

16. A method, comprising:
fabricating a lower layer pattern on a semiconductor substrate, wherein the lower layer pattern includes a first region including first electrical devices and a second region including second electrical devices and one or more electrically nonconductive dummy devices, wherein a first device density of the first electrical devices in the first region is substantially greater than a second device density of the second electrical devices in the second region;
providing a partially-planarizing dielectric layer on the lower layer pattern so as to cover the first electrical devices, the second electrical devices, and the electrically nonconductive dummy devices, wherein an average height above the substrate of a top surface of the partially-planarizing dielectric layer in the first region is approximately the same as the average height above the substrate of the top surface of the partially-planarizing dielectric layer in the second region;
etching the partially-planarizing dielectric layer in the first region and in the second region so as to form a plurality of through-holes in the first region while leaving a portion of the planarizing dielectric layer covering top surfaces of the second electrical devices in the second region; and
providing an electrically conductive material in the through-holes.

17. The method of claim 16, wherein an average height above the substrate of top surfaces of the one or more electrically nonconductive dummy devices is substantially the same as an average height above the substrate of top surfaces of the second electrical devices.

18. The method of claim 16, wherein an average height above the substrate of a top surface of the lower layer pattern in the second region is approximately the same as the average height above the substrate of the top surface of the lower layer pattern in the first region.

19. The method of claim 16, wherein fabricating the lower layer pattern includes:
providing a dummy dielectric material onto the substrate;
masking and patterning the dummy dielectric material to remove a first portion of the dummy dielectric material and to leave a remaining portion of the dummy dielectric material; and
hardening the remaining portion of the dummy dielectric material to produce the one or more electrically nonconductive dummy devices.

20. The method of claim 16, wherein the dummy dielectric material comprises polyimide, and wherein the partially-planarizing dielectric layer comprises benzocyclobutene (BCB).
